(19) United States
(12) Patent Application Publication
(10) Pub. No.: US 2026/0143917 A1
(43) Pub. Date: May 21, 2026

(54) DISPLAY APPARATUS HAVING A LIGHT-EMITTING DEVICE AND AN ENCAPSULATION STRUCTURE

(71) Applicant: LG Display Co., Ltd., Seoul (KR)

(72) Inventors: Hyun KIM, Paju-si (KR); Young Kyun MOON, Paju-si (KR)

(73) Assignee: LG Display Co., Ltd., Seoul (KR)

(21) Appl. No.: 19/190,056

(22) Filed: Apr. 25, 2025

(30) Foreign Application Priority Data
Nov. 20, 2024 (KR) 10-2024-0166097

(51) Int. Cl. H10K 59/122; H10K 59/80

(52) U.S. Cl. CPC H10K 59/122; H10K 59/873

(57) ABSTRACT

A light-emitting device can be disposed at an emission area defined by a bank insulating layer. A spacer can be disposed on the bank insulating layer. The light-emitting device, the bank insulating layer and the spacer can be covered by the encapsulation structure. The encapsulation structure can include a first encapsulating layer, a second encapsulating layer and a third encapsulating layer, which are sequentially stacked. The second encapsulating layer can have a higher fluidity than the first encapsulating layer and the third encapsulating layer. The spacer can have a stacked structure of a conductive pattern, a porous layer and a cap pattern. The second encapsulating layer can be in contact with a side surface of the porous layer. Thus, in the display apparatus, stains due to a difference in level of the upper surface of the encapsulation structure can be prevented.

### CROSS-REFERENCE TO RELATED APPLICATIONS

This application claims the benefit of and priority to Korean Patent Application No. 10-2024-0166097, filed on Nov. 20, 2024, the entire contents of which are incorporated herein by reference for all purposes as if fully set forth herein.

### BACKGROUND

### 1. Technical Field

The present disclosure relates to a display apparatus in which a light-emitting device is covered by an encapsulation structure.

### 2. Description of Related Art

Generally, a display apparatus provides an image to a user. For example, the display apparatus can include light-emitting devices. Each of the light-emitting devices can emit light displaying a specific color. For example, each of the light-emitting devices can include a lower electrode, a light-emitting unit and an upper electrode, which are sequentially stacked.

The light-emitting devices can be disposed on emission areas of a device substrate. The emission areas can be defined by a bank insulating layer. A spacer can be disposed on the bank insulating layer. For example, each of the emission areas can be surrounded by the spacer. An encapsulation structure can be disposed on the light-emitting devices, the bank insulating layer and the spacer. The encapsulation structure can have a multi-layer structure. For example, the encapsulation structure can includes a first inorganic encapsulating layer, an organic encapsulating layer and a second inorganic encapsulating layer, which are sequentially stacked.

The description of related art should not be considered prior art merely because it is mentioned in or associated with this section. The description of related art includes information that describes one or more aspects of the subject technology, and the description in this section does not limit the scope of the invention.

### SUMMARY

Accordingly, one or more aspects of the present disclosure are directed to a display apparatus that substantially obviates one or more problems due to limitations and disadvantages of the related art.

An aspect of the present disclosure is to provide a display apparatus capable of preventing the generation of stains due to a difference in level of an upper surface of the encapsulation structure.

Another aspect of the present disclosure is to provide a display apparatus in which an upper surface of an organic encapsulating layer at an emission area of each pixel area can have a same level.

Additional advantages, aspects, and features of the disclosure will be set forth in part in the description which follows and in part will become apparent to those having ordinary skill in the art upon examination of the following or may be learned from practice of the disclosure. The aspects and other advantages of the disclosure may be realized and attained by the structure particularly pointed out in the written description and claims hereof as well as the appended drawings.

To achieve these aspects and other advantages and in accordance with the purpose of the present disclosure, as embodied and broadly described herein, there is provided a display apparatus comprising a device substrate. A bank insulating layer and a light-emitting device are disposed on the device substrate. The bank insulating layer defines an emission area. The light-emitting device is disposed at the emission area. The light-emitting device includes a lower electrode, a light-emitting unit and an upper electrode, which are sequentially stacked. A spacer is disposed on the bank insulating layer. The spacer has a stacked structure of a conductive pattern, a porous layer and a cap pattern. An encapsulation structure is disposed on the bank insulating layer, the light-emitting device and the spacer. The encapsulation structure includes a first inorganic encapsulating layer, an organic encapsulating layer and a second inorganic encapsulating layer, which are sequentially stacked. The spacer has an under-cut region by the porous layer and the cap pattern. A side surface of the porous layer includes a region exposed by the upper electrode and the first inorganic encapsulating layer.

The organic encapsulating layer can be in contact with the side surface of the porous layer exposed by the upper electrode and the first inorganic encapsulating layer.

The conductive pattern and the cap pattern can include a material having an etch selectivity with the porous layer.

The side surface of the porous layer can have a concave shape with respect to the central portion of the porous layer.

The conductive pattern can include a conductive material. The upper electrode can include a first electrode pattern and a second electrode pattern. The first electrode pattern can overlap the emission area. The second electrode pattern can be separated from the first electrode pattern by the under-cut region. The first electrode pattern can be in contact with the conductive pattern between the light-emitting unit and the porous layer.

The second electrode pattern can include the same material as the first electrode pattern. The resistance of the conductive pattern can be lower than the resistance of the first electrode pattern and the resistance of the second electrode pattern.

The first inorganic encapsulating layer can include a first encapsulating pattern and a second encapsulating pattern. The first encapsulating pattern can overlap the first electrode pattern. The second encapsulating pattern can overlap the second electrode pattern. The second encapsulating pattern can be separated from the first encapsulating pattern by the under-cut region.

A thickness of the porous layer can be greater than a thickness of the first inorganic encapsulating layer.

A buffer pattern can be disposed between the conductive pattern and the porous layer. The buffer pattern can include a material having an etch selectivity with the porous layer.

The buffer pattern can include an inorganic insulating material.

A thickness of the buffer pattern can be the same as a thickness of the first inorganic encapsulating layer.

The porous layer can include the same material as the bank insulating layer.

Additional features, advantages, and aspects of the present disclosure are set forth in part in the description that follows and in part will become apparent from the present disclosure or may be learned by practice of the inventive concepts provided herein. Other features, advantages, and aspects of the present disclosure may be realized and attained by the descriptions provided in the present disclosure, or derivable therefrom, and the claims hereof as well as the drawings. It is intended that all such features, advantages, and aspects be included within this description, be within the scope of the present disclosure, and be protected by the following claims. Nothing in this section should be taken as a limitation on those claims. Further aspects and advantages are discussed below in conjunction with embodiments of the present disclosure.

It is to be understood that both the foregoing description and the following description of the present disclosure are examples, and are intended to provide further explanation of the disclosure as claimed.

### BRIEF DESCRIPTION OF THE DRAWINGS

The accompanying drawings, which are included to provide a further understanding of the present disclosure, are incorporated in and constitute a part of this present disclosure, illustrate aspects and embodiments of the present disclosure, and together with the description serve to explain principles and examples of the disclosure. In the drawings:

FIG. 1 is a view schematically showing a display apparatus according to an embodiment of the present disclosure;

FIG. 2 is an enlarged view of K1 region in FIG. 1;

FIG. 3 is a view showing a circuit of a pixel area in the display apparatus according to the embodiment of the present disclosure;

FIG. 4 is a view taken along I-I′ of FIG. 2;

FIG. 5 is an enlarged view of K2 region in FIG. 4;

FIGS. 6 to 13 are views sequentially showing a method of forming the display apparatus according to the embodiment of the present disclosure;

FIGS. 14 to 17 are views showing the display apparatus according to another embodiment of the present disclosure; and

FIGS. 18 and 19 are views sequentially showing a method of forming the display apparatus according to another embodiment of the present disclosure.

### DETAILED DESCRIPTION

Hereinafter, details related to the above aspects, technical configurations, and operational effects of the embodiments of the present disclosure will be clearly understood by the following detailed description with reference to the drawings, which illustrate some embodiments of the present disclosure. Here, the embodiments of the present disclosure are provided in order to allow the technical sprit of the present disclosure to be satisfactorily transferred to those skilled in the art, and thus the present disclosure may be embodied in other forms and is not limited to the embodiments described below.

In addition, the same or extremely similar elements may be designated by the same reference numerals throughout the specification and in the drawings, the lengths and thickness of layers and regions may be exaggerated for convenience. It will be understood that, when a first element is referred to as being “on” a second element, although the first element may be disposed on the second element so as to come into contact with the second element, a third element may be interposed between the first element and the second element.

Here, terms such as, for example, “first” and “second” may be used to distinguish any one element with another element. However, the first element and the second element may be arbitrary named according to the convenience of those skilled in the art without departing the technical sprit of the present disclosure.

The terms used in the specification of the present disclosure are merely used in order to describe particular embodiments, and are not intended to limit the scope of the present disclosure. For example, an element described in the singular form is intended to include a plurality of elements unless the context clearly indicates otherwise. For example, an element may be one or more elements. An element may include a plurality of elements. The word “exemplary” is used to mean serving as an example or illustration. Embodiments are example embodiments. Aspects are example aspects. In one or more implementations, “embodiments,” “examples,” “aspects,” and the like should not be construed to be preferred or advantageous over other implementations. An embodiment, an example, an example embodiment, an aspect, or the like may refer to one or more embodiments, one or more examples, one or more example embodiments, one or more aspects, or the like, unless stated otherwise. Further, the term “may” encompasses all the meanings of the term “can.” In addition, in the specification of the present disclosure, it will be further understood that each of the terms “comprise,” “have,” “include” and the like specifies the presence of stated features, integers, steps, operations, elements, components, and/or combinations thereof, but does not preclude the presence or addition of one or more other features, integers, steps, operations, elements, components, and/or combinations.

And, unless “directly” is used, the terms “connected” and “coupled” may include that two components are “connected” or “coupled” through one or more other components located between the two components.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning that is consistent with their meaning in the context of the relevant art and should not be interpreted in an idealized or overly formal sense unless expressly so defined herein.

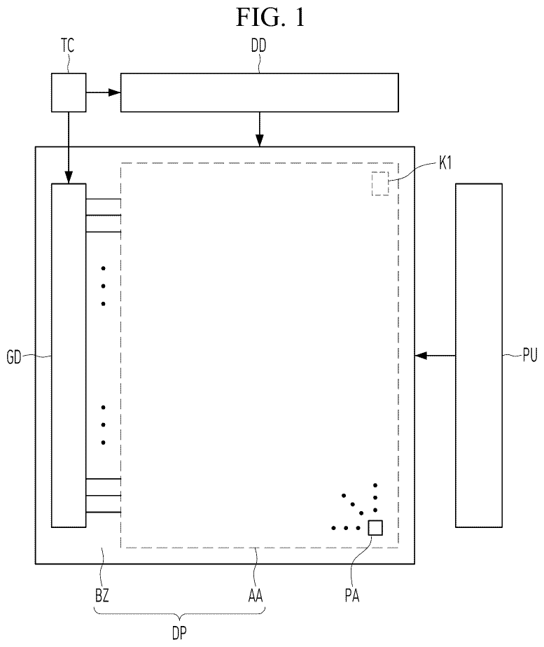

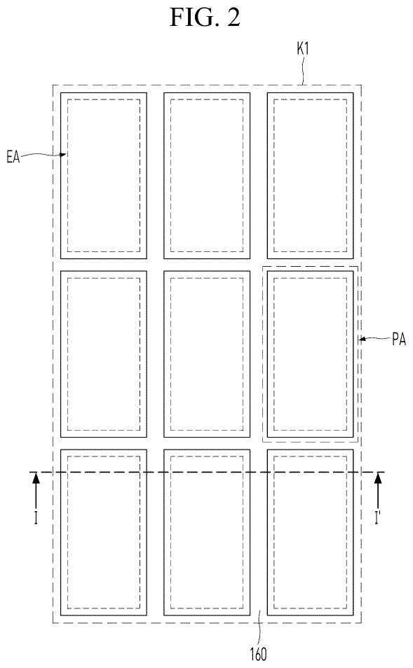

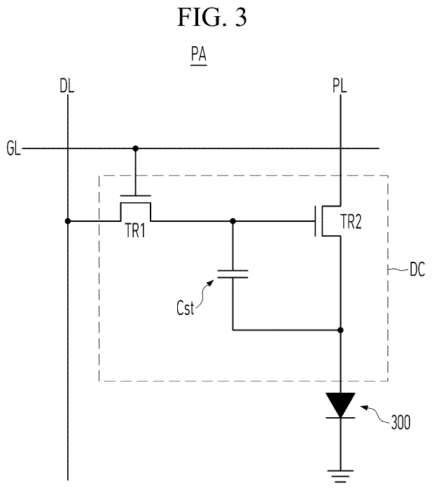

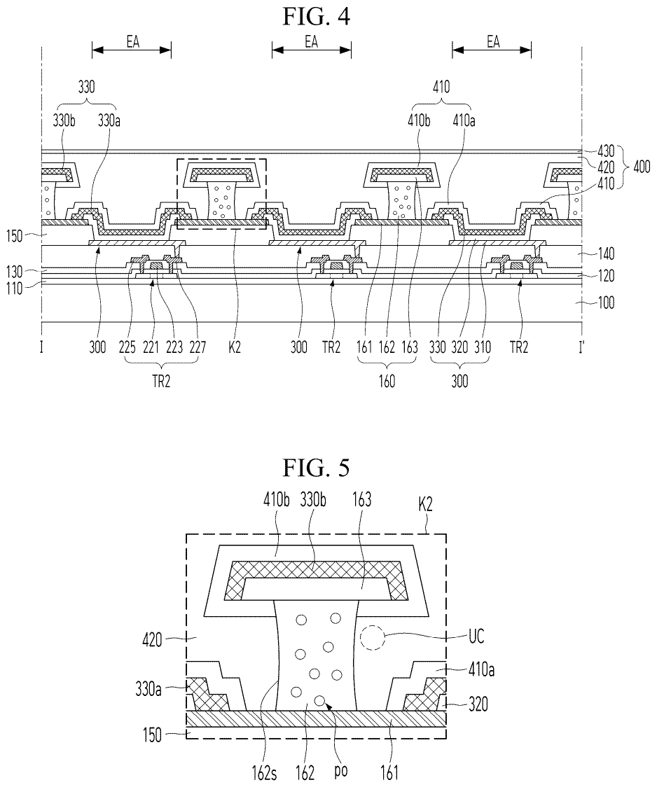

FIG. 1 is a view schematically showing a display apparatus according to an embodiment of the present disclosure. FIG. 2 is an enlarged view of K1 region in FIG. 1. FIG. 3 is a view showing a circuit of a pixel area in the display apparatus according to the embodiment of the present disclosure. FIG. 4 is a view taken along I-I′ of FIG. 2. FIG. 5 is an enlarged view of K2 region in FIG. 4.

Referring to FIGS. 1 to 5, the display apparatus according to the embodiment of the present disclosure can include a display panel DP. The display panel DP can generate an image provided to a user. For example, pixel areas PA can be disposed within the display panel DP. The pixel areas PA can be disposed side by side in a first direction X and a second direction Y perpendicular to the first direction X. For example, the pixel areas PA can be arranged in a matrix shape. Various signals can be applied in each pixel area PA through signal wirings GL, DL and PL. The signal wirings GL, DL and PL can include a gate line GL applying a gate signal, a data line DL applying a data signal, and a power voltage supply line PL supplying a power voltage.

The display panel DP can include an active area AA in which the pixel areas PA are disposed, and a bezel area BZ being disposed outside the active area AA. The signal wirings GL, DL and PL can be electrically connected to each pixel area PA through the bezel area BZ. For example, the active area AA can be surrounded by the bezel area BZ. A gate driver GD electrically connected to the gate line GL, a data driver DD electrically connected to the data line DL, a power unit PU electrically connected to the power voltage supply line PL, and a timing controller TC controlling the gate driver GD and the data driver DD can be disposed outside the active area AA. At least one of the gate driver GD, the data driver DD, the power unit PU and the timing controller TC can be disposed on the bezel area BZ. For example, the display apparatus according to the embodiment of the present disclosure can be a GIP (Gate In Panel) type display apparatus in which the gate driver GD is formed on the bezel area BZ.

Each of the pixel areas PA can realize a specific color. For example, a driving circuit DC electrically connected to the signal wirings GL, DL and PL, and a light-emitting device 300 electrically connected to the driving circuit DC can be disposed within each pixel area PA. The driving circuit DC can supply a driving current corresponding to the data signal to the light-emitting device 300 according to the gate signal using the power voltage. The driving current supplied by the driving circuit DC can be maintained for one frame. For example, the driving circuit DC can include a first thin film transistor TR1, a second thin film transistor TR2 and a storage capacitor Cst.

The first thin film transistor TR1 can transmit the data signal to the second thin film transistor TR2 according to the gate signal. For example, the first thin film transistor TR1 can function as a switching thin film transistor. The first thin film transistor TR1 can include a first semiconductor pattern, a first gate electrode, a first drain electrode and a first source electrode. For example, the first gate electrode can be electrically connected to the gate line GL, and the first drain electrode can be electrically connected to the date line DL.

The second thin film transistor TR2 can generate the driving current corresponding to the data signal. For example, the second thin film transistor TR2 can function as a driving thin film transistor. The second thin film transistor TR2 can include a second semiconductor pattern 221, a second gate electrode 223, a second drain electrode 225 and a second source electrode 227. For example, the second gate electrode 223 can be electrically connected to the first source electrode, and the second drain electrode 225 can be electrically connected to the power voltage supply line PL.

The second semiconductor pattern 221 can include a semiconductor material. For example, the second semiconductor pattern 221 can include an oxide semiconductor, such as IGZO. The second semiconductor pattern 221 can include a drain region, a channel region and a source region. The channel region can be disposed between the drain region and the source region. The resistance of the drain region and the resistance of the source region can smaller that the resistance of the channel region. For example, the drain region and the source region can include a conductive region of an oxide semiconductor. The channel region can be a region of an oxide semiconductor, which is not conductorized.

The second semiconductor pattern 221 can include a same material as the first semiconductor pattern. The second semiconductor pattern 221 can be disposed on a same layer as the first semiconductor pattern. The second semiconductor pattern 221 can be formed by a same process as the first semiconductor pattern. For example, the second semiconductor pattern 221 can be formed simultaneously with the first semiconductor pattern.

The second gate electrode 223 can be disposed on a portion of the second semiconductor pattern 221. For example, the second gate electrode 223 can overlap the channel region of the second semiconductor pattern 221. The second gate electrode 223 can include a conductive material. For example, the second gate electrode 223 can include a metal, such as aluminum (Al), chrome (Cr), copper (Cu), molybdenum (Mo), titanium (Ti) and tungsten (W). The second gate electrode 223 can be spaced apart from the second semiconductor pattern 221. The second gate electrode 223 can be insulated from the second semiconductor pattern 221. For example, the channel region of the second semiconductor pattern 221 can have an electrical conductivity corresponding to a voltage of a signal applied to the second gate electrode 223.

The second gate electrode 223 can include a same material as the first gate electrode. The second gate electrode 223 can be disposed on a same layer as the first gate electrode. The second gate electrode 223 can be formed by a same process as the first gate electrode. For example, the second gate electrode 223 can be formed simultaneously with the first gate electrode.

The second drain electrode 225 can be electrically connected to the drain region of the second semiconductor pattern 221. The second drain electrode 225 can include a conductive material. For example, the second drain electrode 225 can include a metal, such as aluminum (Al), chrome (Cr), copper (Cu), molybdenum (Mo), titanium (Ti) and tungsten (W). The second drain electrode 225 can be insulated from the second gate electrode 223. The second drain electrode 225 can include a different material from the second gate electrode 223. For example, the second drain electrode 225 can be disposed on a different layer from the second gate electrode 223.

The second drain electrode 225 can include a same material as the first drain electrode. The second drain electrode 225 can be disposed on a same layer as the first drain electrode. The second drain electrode 225 can be formed by a same process as the first drain electrode. For example, the second drain electrode 225 can be formed simultaneously with the first drain electrode.

The second source electrode 227 can be electrically connected to the source region of the second semiconductor pattern 221. The second source electrode 227 can include a conductive material. For example, the second source electrode 227 can include a metal, such as aluminum (Al), chrome (Cr), copper (Cu), molybdenum (Mo), titanium (Ti) and tungsten (W). The second source electrode 227 can be insulated from the second gate electrode 223. The second source electrode 227 can include a different material from the second gate electrode 223. For example, the second source electrode 227 can be disposed on a different layer from the second gate electrode 223.

The second source electrode 227 can be disposed on a same layer as the second drain electrode 225. The second source electrode 227 can include a same material as the second drain electrode 225. The second source electrode 227 can be formed by a same process as the second drain electrode 225. For example, the second source electrode 227 can be formed simultaneously with the second drain electrode 225. The second source electrode 227 can be spaced apart from the second drain electrode 225.

The second source electrode 227 can include a same material as the first source electrode. The second source electrode 227 can be disposed on a same layer as the first source electrode. The second source electrode 227 can be formed by a same process as the first source electrode. For example, the second source electrode 227 can be formed simultaneously with the first source electrode.

The storage capacitor Cst can maintain a voltage of a signal applied to the second gate electrode 223 for one frame. The storage capacitor Cst can have a stacked structure of capacitor electrodes. For example, the storage capacitor Cst can have a structure in which a first capacitor electrode electrically connected to the second gate electrode 233 and a second capacitor electrode electrically connected to the second source electrode 227 are stacked. The storage capacitor Cst can be formed using a process of forming the first thin film transistor TR1 and the second thin film transistor TR2. For example, the first capacitor electrode can be formed simultaneously with the second gate electrode 223, and the second capacitor electrode can be formed simultaneously with the second source electrode 227.

The driving circuit DC of each pixel area PA can be supported by a device substrate 100. The device substrate 100 can include an insulating material. For example, the device substrate 100 can include glass or plastic. At least one insulating layer 110, 120, 130, 140 and 150 for preventing unnecessary electrical connection can be disposed on the device substrate 100. For example, a buffer insulating layer 110, a gate insulating layer 120, an interlayer insulating layer 130, a planarization layer 140 and a bank insulating layer 150 can be disposed on the device substrate 100.

The buffer insulating layer 110 can be disposed close to the device substrate 100. The buffer insulating layer 110 can prevent pollution due to the device substrate 100 in a process of forming the driving circuit DC of each pixel area PA. For example, an upper surface of the device substrate 100 toward the driving circuit DC of each pixel area PA can be covered by the buffer insulating layer 110. The first thin film transistor TR1, the second thin film transistor TR2 and the storage capacitor Cst of each pixel area PA can be disposed on the buffer insulating layer 110. For example, the buffer insulating layer 110 can be in direct contact with the upper surface of the device substrate 100. The buffer insulating layer 110 can include an insulating material. For example, the buffer insulating layer 110 can include an inorganic insulating material, such as silicon oxide (SiOx) and silicon nitride (SiNx). The buffer insulating layer 110 can have a multi-layer structure. For example, the buffer insulating layer 110 can have a structure in which an inorganic insulating layer made of silicon oxide (SiOx) and an inorganic insulating layer made of silicon nitride (SiNx) are stacked.

The gate insulating layer 120 can be disposed on the buffer insulating layer 110. The second gate electrode 223 of each pixel area PA can be insulated from the second semiconductor pattern 221 of the corresponding pixel area PA by the gate insulating layer 120. For example, the gate insulating layer 120 can cover the first semiconductor pattern and the second semiconductor pattern 221 of each pixel area PA. The first gate electrode and the second gate electrode 223 of each pixel area PA can be disposed on the gate insulating layer 120. The gate insulating layer 120 can include an insulating material. For example, the gate insulating layer 120 can be an inorganic insulating layer made of an inorganic insulating material, such as silicon oxide (SiOx) and silicon nitride (SiNx).

The interlayer insulating layer 130 can be disposed on the gate insulating layer 120. The second drain electrode 225 and the second source electrode 227 of each pixel area PA may be insulated from the second gate electrode 223 of the corresponding pixel area PA by the interlayer insulating layer 130. For example, the interlayer insulating layer 130 can cover the first gate electrode and the second gate electrode 223 of each pixel area PA. The first drain electrode, the first source electrode, the second drain electrode 225 and the second source electrode 227 of each pixel area PA can be disposed on the interlayer insulating layer 130. The interlayer insulating layer 130 can include an insulating material. For example, the interlayer insulating layer 130 can be an inorganic insulating layer made of an inorganic insulating material.

The planarization layer 140 can be disposed on the interlayer insulating layer 130. A thickness difference due to the driving circuit DC of each pixel area PA can be removed by the planarization layer 140. For example, the first drain electrode, the first source electrode, the second drain electrode 225 and the second source electrode 227 of each pixel area PA can be covered by the planarization layer 140. An upper surface of the planarization layer 140 opposite to the device substrate 100 can be flat. For example, the upper surface of the planarization layer 140 can be parallel to the upper surface of the device substrate 100. The planarization layer 140 can include an insulating material. The planarization layer 140 can include a material having a relatively high fluidity. For example, the planarization layer 140 can be an organic insulating layer made of an organic insulating material.

The bank insulating layer 150 can be disposed on the planarization layer 140. The bank insulating layer 150 can define an emission area EA in each pixel area PA. For example, a portion of the upper surface of the planarization layer 140 overlapping with the emission area EA of each pixel area PA can be exposed by the bank insulating layer 150. The emission area EA of each pixel area PA can be surrounded by the bank insulating layer 150. The bank insulating layer 150 can include an insulating material. For example, the bank insulating layer 150 can be an organic insulating layer made of an organic insulating material. The bank insulating layer 150 can include a different material from the planarization layer 140.

The light-emitting device 300 of each pixel area PA can emit light displaying a specific color. For example, the light-emitting device 300 of each pixel area PA can have a stacked structure of a lower electrode 310, a light-emitting unit 320 and an upper electrode 330. The light-emitting device 300 of each pixel area PA can be disposed on the upper surface of the planarization layer 140. The light-emitting device 300 of each pixel area PA can overlap the emission area EA defined in the corresponding pixel area PA. For example, the lower electrode 310, the light-emitting unit 320 and the upper electrode 330 of each pixel area PA can be sequentially stacked on a portion of the planarization layer 140 of the corresponding pixel area PA exposed by the bank insulating layer 150.

The lower electrode 310 can include a conductive material. The lower electrode 310 can include a material having relative high reflectance. For example, the lower electrode 310 can include a metal, such as aluminum (Al) and silver (Ag). The lower electrode 310 can have a multi-layer structure. For example, the lower electrode 310 can have a structure in which a reflective electrode made of a metal is disposed between transparent electrodes made of a transparent conductive material, such as ITO and IZO.

The light-emitting unit 320 can generate light having luminance corresponding to a voltage difference between the lower electrode 310 and the upper electrode 330. For example, the light-emitting unit 320 can include an emission material layer (EML). The emission material layer can include an organic emission material, an inorganic emission material, or a hybrid emission material. For example, the display apparatus according to the embodiment of the present disclosure can be an organic light-emitting display apparatus including an organic emission material. The light-emitting unit 320 can have a multi-layer structure. For example, the light-emitting unit 320 can include at least one of a hole injection layer (HIL), a hole transport layer (HTL), an electron transport layer (ETL) and an electron injection layer (EIL). Thus, in the display apparatus according to the embodiment of the present disclosure, the efficiency of the light-emitting unit 320 can be improved.

The upper electrode 330 can include a conductive material. The upper electrode 330 can include a different material from the lower electrode 310. A transmittance of the upper electrode 330 can be larger than a transmittance of the lower electrode 310. For example, the upper electrode 330 can be a transparent electrode made of a transparent conductive material, such as ITO and IZO. The upper electrode 330 can have a different work-function from the lower electrode 310. For example, a work-function of the upper electrode 330 can be lower than a work-function of the lower electrode 310. Thus, in the display apparatus according to the embodiment of the present disclosure, the lower electrode 310 of each pixel area PA can function as anode, and the upper electrode 330 of each pixel area PA can function as cathode.

The driving current generated by the driving circuit DC of each pixel area PA can be supplied to the lower electrode 310 of the corresponding pixel area PA. For example, the lower electrode 310 of each pixel area PA can be in direct contact with the second source electrode 227 of the corresponding pixel area PA by penetrating the planarization layer 140. The lower electrode 310 of each pixel area PA can be insulated from the lower electrode 310 of adjacent pixel area PA by the bank insulating layer 150. For example, an edge of the lower electrode 310 in each pixel area PA can be covered by the bank insulating layer 150. The light-emitting unit 320 and the upper electrode 330 of each pixel area PA can be stacked on a portion of the corresponding lower electrode 310 exposed by the bank insulating layer 150. For example, the light-emitting unit 320 can be in direct contact with the lower electrode 310 and upper electrode 330 in the emission area EA of each pixel area PA. Thus, in the display apparatus according to the embodiment of the present disclosure, light can only be emitted from the emission area EA of each pixel area PA.

A connection region of the second source electrode 227 and the lower electrode 310 in each pixel area PA can be disposed outside the emission area EA defined in the corresponding pixel area PA. For example, a portion of the first electrode 310 overlapping with the emission area EA in each pixel area PA can be in direct contact with the upper surface of the planarization layer 140. Thus, in the display apparatus according to the embodiment of the present disclosure, a portion of the lower electrode 310 overlapping with the emission area EA of each pixel area PA can be flat. Therefore, in the display apparatus according to the embodiment of the present disclosure, the luminance deviation depending on the generation location of the light emitted from the emission area EA of each pixel area PA can be prevented.

The light emitted from the light-emitting device 300 of each pixel area PA can display a different color from the light-emitting device 300 of adjacent pixel area PA. For example, the emission material layer of each pixel area PA can include a different material from the emission material layer of adjacent pixel area PA. The light-emitting unit 320 of each pixel area PA can be spaced apart from the light-emitting unit 320 of adjacent pixel area PA. For example, an edge of the light-emitting unit 320 of each pixel area PA can be disposed on the bank insulating layer 150.

The emission material layer of each pixel area PA can be sequentially formed. For example, a process of forming the light-emitting unit 320 of each pixel area PA can include a deposition process using a fine metal mask (FMM). A spacer 160 can be disposed on an upper surface of the bank insulating layer 150 opposite to the device substrate 100. The fine metal mask can be supported by the spacer 160. An upper surface of the spacer 160 opposite to the device substrate 100 can have a level significantly higher than a lower surface of the upper electrode 330 of each pixel area PA toward the device substrate 100. For example, a distance between the upper surface of the device substrate 100 and the upper surface of the spacer 160 can be significantly larger than a distance between the upper surface of the device substrate 100 and the lower surface of the upper electrode 330 of each pixel area PA. Thus, in the display apparatus according to the embodiment of the present disclosure, the damage of the light-emitting unit 320 formed in the adjacent pixel area PA and the inflow of particles into the adjacent pixel area PA in the deposition process using the fine metal mask can be prevented.

The spacer 160 can extend along the upper surface of the bank insulating layer 150. For example, the spacer 160 can surround the emission area EA of each pixel area PA. The spacer 160 can have a multi-layer structurer. For example, the spacer 160 can have a stacked structure of a conductive pattern 161, a porous layer 162 and a cap pattern 163.

The conductive pattern 161 can be disposed close to the bank insulating layer 150. For example, the conductive pattern 161 can be in direct contact with the upper surface of the bank insulating layer 150. The conductive pattern 161 can be spaced apart from the lower electrode 310 of each pixel area PA. The conductive pattern 161 can be disposed outside the emission area EA defined in each pixel area PA. For example, the conductive pattern 161 can be disposed in a non-emission area that is disposed between the emission areas EA. The conductive pattern 161 can be insulated from the lower electrode 310 of each pixel area PA by the bank insulating layer 150. The conductive pattern 161 can include a conductive material. The conductive pattern 161 can include a material having a relative low resistance. For example, the conductive pattern 161 can include a metal, such as aluminum (Al), chrome (Cr), copper (Cu), molybdenum (Mo), titanium (Ti) and tungsten (W).

A porous layer 162 can be disposed on the conductive pattern 161. The porous layer 162 can have a smaller size than the conductive pattern 161. For example, a side surface 162s of the porous layer 162 can overlap an upper surface of the conductive pattern 161 opposite to the device substrate 100. The porous layer 162 can overlap the central portion of the conductive pattern 161. For example, an edge of the conductive pattern 161 can be disposed outside the porous layer 162. The side surface 162s of the porous layer 162 can have a concave shape with respect to the central portion of the porous layer 162.

The porous layer 162 can include a different material from the conductive pattern 161. The porous layer 162 can include an insulating material. For example, the porous layer 162 can be an organic insulating layer made of an organic insulating material. Thus, in the display cavity apparatus according to the embodiment of the present disclosure, the conductive pattern 161 can't be removed by a solution used in a process of etching the porous layer 162. That is, in the display apparatus according to the embodiment of the present disclosure, the conductive pattern 161 can have an etch selectivity with the porous layer 162. The porous layer 162 can include a plurality of fine pores po. For example, in the display apparatus according to the embodiment of the present disclosure, liquid or gas can penetrate into the plurality of fine pores po of the porous layer 162.

The cap pattern 163 can be disposed on the porous layer 162. A size of the cap pattern 163 can be greater than a size of the porous layer 162. For example, the side surface 162s of the porous layer 162 can overlap a lower surface of the cap pattern 163 toward the conductive pattern 161. An edge of the cap pattern 163 can be disposed outside the porous layer 162. For example, the spacer 160 can include an under-cut region UC by the porous layer 162 and the cap pattern 163. The cap pattern 163 can be the uppermost layer of the spacer 160. For example, the upper surface of the spacer 160 can be an upper surface of the cap pattern 163 opposite to the device substrate 100.

The cap pattern 163 can have a smaller size than the conductive pattern 161. For example, the edge of the conductive pattern 161 can be disposed outside the cap pattern 163. The edge of the conductive pattern 161 can be covered by the light-emitting unit 320 in one of the pixel areas PA. The cap pattern 163 can't overlap the light-emitting unit 320 of each pixel area PA. For example, the light-emitting unit 320 of each pixel area PA can be spaced apart from the side surface 162s of the porous layer 162. The upper surface of the conductive pattern 161 can include a region that does not overlap the light-emitting unit 320 of each pixel area PA and the porous layer 162.

The cap pattern 163 can include an insulating material. Thus, in the display apparatus according to the embodiment of the present disclosure, the damage of the fine metal mask due to the spacer 160 can be prevented. The cap pattern 163 can include a different material from the porous layer 162. For example, the cap pattern 163 can be an inorganic insulating layer made of an inorganic insulating material. Thus, in the display apparatus according to the embodiment of the present disclosure, the cap pattern 163 can be removed slower than the porous layer 162 in a process of etching the porous layer 162.

The upper electrode 330 of each pixel area PA can be formed by a same process as the upper electrode 330 of adjacent pixel PA. For example, the upper electrode 330 of each pixel area PA can be formed simultaneously with the upper electrode 330 of adjacent pixel PA. Thus, in the display apparatus according to the embodiment of the present disclosure, a process of forming the upper electrode 330 of each pixel area PA can be simplified. The upper electrode 330 can be partially separated by the under-cut region UC of the spacer 160. For example, the upper electrode 330 can include a first electrode pattern 330a overlapping with the emission area EA of each pixel area PA and a second electrode pattern 330b separated from the first electrode pattern 330a by the under-cut region UC.

The first electrode pattern 330a can cover the light-emitting unit 320 of each pixel area PA. For example, an edge of the first electrode pattern 330a can be disposed between the light-emitting unit 320 of each pixel area PA and the porous layer 162. The first electrode pattern 330a can be in direct contact with the upper surface of the conductive pattern 161 between the light-emitting unit 320 of each pixel area PA and the porous layer 162. Thus, in the display apparatus according to the embodiment of the present disclosure, the first electrode pattern 330a disposed on each pixel area PA can be electrically connected to the first electrode pattern 330a disposed on adjacent pixel area PA through the conductive pattern 161. That is, in the display apparatus according to the embodiment of the present disclosure, a voltage applied to the first electrode pattern 330a of each pixel area PA can be the same as a voltage applied to the first electrode pattern 330a of adjacent pixel area PA. The resistance of the conductive pattern 161 can be smaller than the resistance of the first electrode pattern 330a. For example, the conductive pattern 161 can have a higher electrical conductivity than the first electrode pattern 330a. Therefore, in the display apparatus according to the embodiment of the present disclosure, the delay of a signal applied to the first electrode pattern 330a of each pixel area PA can be minimized.

The second electrode pattern 330b can be disposed on the cap pattern 163. For example, the upper surface of the cap pattern 163 can be covered by the second electrode pattern 330b. The second electrode pattern 330b can include a same material as the first electrode pattern 330a. For example, a thickness of the second electrode pattern 330b on the upper surface of the cap pattern 163 can be the same as a thickness of the first electrode pattern 330a. The second electrode pattern 330b can't be in contact with the side surface 162s of the porous layer 162. For example, the first electrode pattern 330a and the second electrode pattern 330b can expose the side surface 162s of the porous layer 162. The side surface 162s of the porous layer 162 can include a region disposed between the first electrode pattern 330a and the second electrode pattern 330b. Thus, in the display apparatus according to the embodiment of the present disclosure, the second electrode pattern 330b can be insulated from the first electrode pattern 330a by the spacer 160. For example, in the display apparatus according to the embodiment of the present disclosure, the second electrode pattern 330b can be in a floating state.

An encapsulation structure 400 can be disposed on the light-emitting device 300 of each pixel area PA. The encapsulation structure 400 can prevent the damage of the light-emitting device 300 in each pixel area PA due to external impact and moisture. For example, the light-emitting device 300 of each pixel area PA can be completely covered by the encapsulation structure 400. The encapsulation structure 400 can extend beyond the emission area EA defined in each pixel area PA. For example, the bank insulating layer 150 and the spacer 160 can overlap the encapsulation structure 400. The encapsulation structure 400 can remove a thickness difference due to the light-emitting device 300 of each pixel area PA and the spacer 160. For example, the spacer 160 can be completely covered by the encapsulation structure 400. An upper surface of the encapsulation structure 400 opposite to the device substrate 100 can have a higher level than the upper surface of the cap pattern 163. For example, a distance between the upper surface of the device substrate 100 and the upper surface of the encapsulation structure 400 can be larger than a distance between the upper surface of the device substrate 100 and the upper surface of the cap pattern 163.

The encapsulation structure 400 can have a multi-layer structure. For example, the encapsulation structure 400 can include a first encapsulating layer 410, a second encapsulating layer 420 and a third encapsulating layer 430, which are sequentially stacked. The first encapsulating layer 410, the second encapsulating layer 420 and the third encapsulating layer 430 can include an insulating material. The second encapsulating layer 420 can include a different material from the first encapsulating layer 410 and the third encapsulating layer 430. The second encapsulating layer 420 can include a material having a relatively high fluidity. For example, the first encapsulating layer 410 and the third encapsulating layer 430 can be an inorganic encapsulating layer made of an inorganic insulating material, and the second encapsulating layer 420 can be an organic encapsulating layer made of an organic insulating material.

The first encapsulating layer 410 can be disposed close to the upper electrode 330. For example, the first encapsulating layer 410 can include a first encapsulating pattern 410a being in direct contact with the first electrode pattern 330a and a second encapsulating pattern 410b being in direct contact with the second electrode pattern 410b. The under-cut region UC of the spacer 160 can partially separate the first encapsulating layer 410. For example, the second encapsulating pattern 410b can be spaced apart from the first encapsulating pattern 410a by the under-cut region UC of the spacer 160.

The first encapsulating pattern 410a can cover the first electrode pattern 330a. For example, an edge of the first encapsulating pattern 410a can be disposed outside the first electrode pattern 330a. The first encapsulating pattern 410a can be spaced apart from the side surface 162s of the porous layer 162. For example, the edge of the first encapsulating pattern 410a can be disposed between the first electrode pattern 330a and the porous layer 162.

The second encapsulating pattern 410b can include a same material as the first encapsulating pattern 410a. For example, a thickness of the second encapsulating pattern 410b on the upper surface of the cap pattern 163 can be the same as a thickness of the first encapsulating pattern 410a. The second electrode pattern 330b can be covered by the second encapsulating pattern 410b. The second encapsulating pattern 410b can include a material having higher step coverage than the second electrode pattern 330b. For example, the lower surface of the cap pattern 163 can include a region being in contact with the second encapsulating pattern 410b.

The side surface 162s of the porous layer 162 can include a region that is not covered by the first encapsulating pattern 410a and the second encapsulating pattern 410b. For example, the first encapsulating pattern 410a and the second encapsulating pattern 410b can expose at least portion of the side surface 162s of the porous layer 162. The side surface 162s of the porous layer 162 can include a region disposed between the first encapsulating pattern 410a and the second encapsulating pattern 410b. For example, the porous layer 162 can have a greater thickness than the first encapsulating pattern 410a and the second encapsulating pattern 410b.

The second encapsulating layer 420 can be disposed on the first encapsulating layer 410. The second encapsulating layer 420 can have a greater thickness than the first encapsulating layer 410. For example, a thickness difference due to the light-emitting device 300 of each pixel area PA and the spacer 160 can be removed by the second encapsulating layer 420. An upper surface of the second encapsulating layer 420 opposite to the device substrate 100 can be flat. The upper surface of the second encapsulating layer 420 can have a higher level than the upper surface of the spacer 160. For example, a distance between the upper surface of the device substrate 100 and the upper surface of the second encapsulating layer 420 can be larger than a distance between the upper surface of the device substrate 100 and the upper surface of the spacer 160. The second encapsulating pattern 410b can be covered by the second encapsulating layer 420.

The side surface 162s of the porous layer 162 can be surrounded by the second encapsulating layer 420. For example, the second encapsulating layer 420 can be in direct contact with a region of the side surface 162s of the porous layer 162 exposed by the first encapsulating pattern 410a and the second encapsulating pattern 410b. That is, in the display apparatus according to the embodiment of the present disclosure, the second encapsulating layer 420 can be in direct contact with the porous layer 162 between the conductive pattern 161 and the cap pattern 163. Thus, in the display apparatus according to the embodiment of the present disclosure, the plurality of fine pores po disposed inside the porous layer 162 can be filled by the second encapsulating layer 420.

The third encapsulating layer 430 can be disposed on the second encapsulating layer 420. The upper surface of the second encapsulating layer 420 can be covered by the third encapsulating layer 430. For example, the light-emitting device 300 of each pixel area PA, the bank insulating layer 150 and the spacer 160 can overlap the third encapsulating layer 430. The third encapsulating layer 430 can include a region overlapping with the second encapsulating pattern 410b.

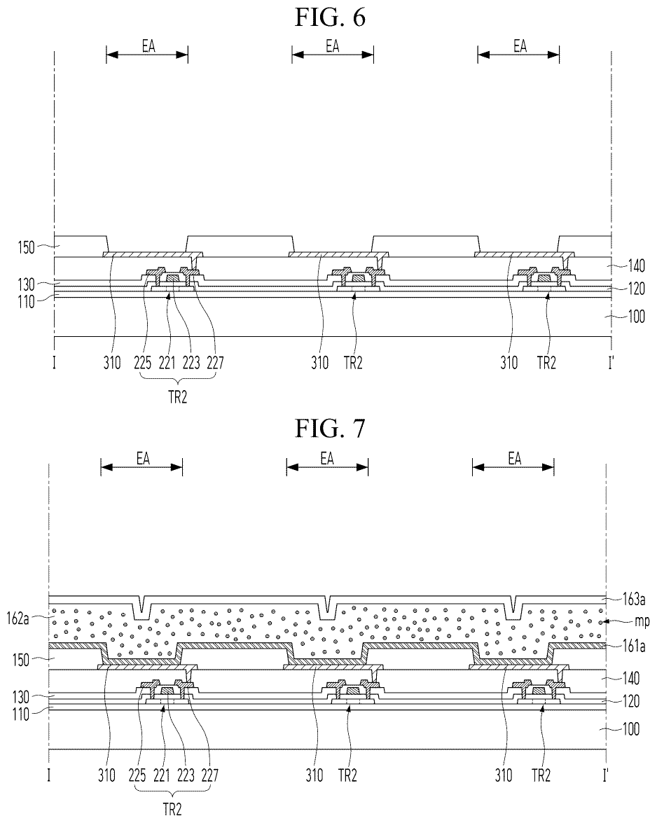

FIGS. 6 to 13 are views sequentially showing a method of forming the display apparatus according to the embodiment of the present disclosure.

The method of forming the display apparatus according to the embodiment of the present disclosure will be described with reference to FIGS. 4 to 13. First, as shown in FIG. 6, the method of forming the display apparatus according to the embodiment of the present disclosure can include a step of forming the buffer insulating layer 110, the gate insulating layer 120, the interlayer insulating layer 130 and the planarization layer 140 on the device substrate 100, a step of forming the driving circuit DC including the second thin film transistor TR2 between the buffer insulating layer 110 and the planarization layer 140 of each pixel area PA, a step of forming the lower electrode 310 electrically connected to the corresponding driving circuit DC on the planarization layer 140 of each pixel area PA, and a step of forming the bank insulating layer 150 defining the emission area EA of each pixel area PA on the planarization layer 140.

The bank insulating layer 150 can be formed of an insulating material. For example, the bank insulating layer 150 can be formed of an organic insulating material. The emission area EA of each pixel area PA can overlap a portion of the lower electrode 310 of the corresponding pixel area PA. For example, the step of forming the bank insulating layer 150 can include a step of forming the bank insulating layer 150 on the entire surface of the device substrate 100 in which the lower electrode 310 of each pixel area PA is formed, and a step of forming openings partially exposing the lower electrode 310 of each pixel area PA in the bank insulating layer 150. The edge of the lower electrode 310 in each pixel area PA can be covered by the bank insulating layer 150.

As shown in FIG. 7, the method of forming the display apparatus according to the embodiment of the present disclosure can include a step of forming a conductive layer 161a on the entire surface of the device substrate 100 in which the bank insulating layer 150 is formed, a step of forming an intermediate insulating layer 162a on the conductive layer 161a, and a step of forming a cap insulating layer 163a on the intermediate insulating layer 162a.

The conductive layer 161a can be formed of a conductive material. The conductive layer 161a can be formed of a material having a relative low resistance. The conductive layer 161a can be formed of a material having a relatively high electrical conductivity. For example, the conductive layer 161a can be formed of a metal.

The intermediate insulating layer 162a can be formed of an insulating material. For example, the intermediate insulating layer 162a can be formed of an organic insulating material. The intermediate insulating layer 162a can be formed to be thicker than the conductive layer 161a. A plurality of fine particles mp can be dispersed in the intermediate insulating layer 162a. For example, the step of forming the intermediate insulating layer 162a can include a step of coating an organic insulating material in which the plurality of fine particles mp is dispersed on the conductive layer 161a. The plurality of fine particles mp can include a different material from the intermediate insulating layer 162a. The plurality of fine particles mp dispersed in the intermediate insulating layer 162a can be selectively removed. For example, the plurality of fine particles mp can be formed of a material having an etch selectivity with the intermediate insulating layer 162a. The plurality of fine particles mp can be formed of a metal. The plurality of fine particles mp can be formed of a different material from the conductive layer 161a.

The cap insulating layer 163a can be formed of an insulating material. The cap insulating layer 163a can be formed of a different material from the intermediate insulating layer 162a. The cap insulating layer 163a can be formed of a material that is etched relatively slowly in a process of etching the intermediate insulating layer 162a. For example, the cap insulating layer 163a can be formed of an inorganic insulating material.

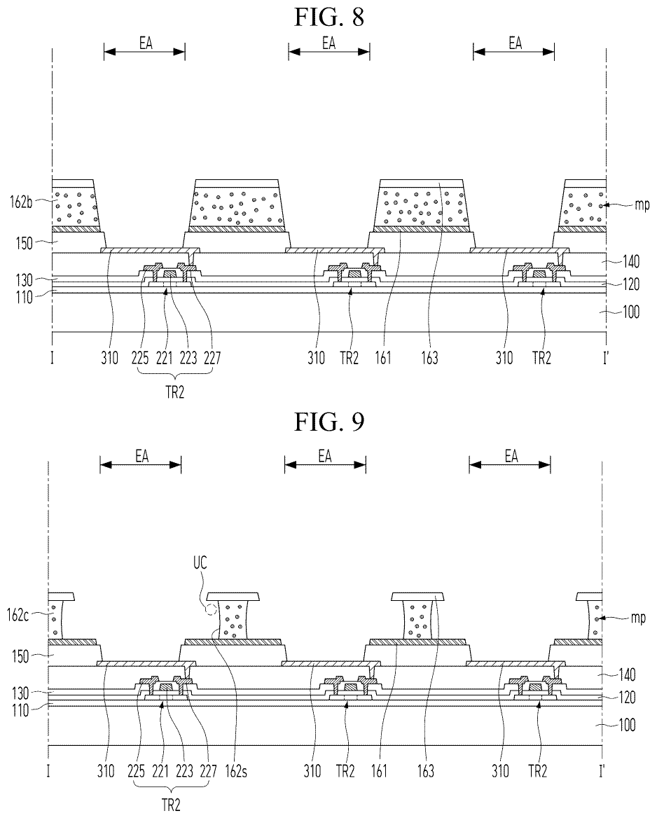

As shown in FIG. 8, the method of forming the display apparatus according to the embodiment of the present disclosure can include a step of forming the conductive pattern 161, a first intermediate pattern 162b and the cap pattern 163, which are sequentially stacked on the upper surface of the bank insulating layer 150.

The conductive pattern 161 can be formed by a process of removing a portion of the conductive layer 161a. The first intermediate pattern 162b can be formed by a process of removing a portion of the intermediate insulating layer 162a. The cap pattern 163 can be formed by a process of removing a portion of the cap insulating layer 163a. The plurality of fine particles mp remained in a region from which the intermediate insulating layer 162a is removed can be removed by a cleaning process.

The conductive pattern 161, the first intermediate pattern 162b and the cap pattern 163 can be formed by using a single mask. For example, the step of forming the conductive pattern 161, the first intermediate pattern 162b and the cap pattern 163 can include a step of forming mask including openings that overlap the emission area EA of each pixel area PA on the cap insulating layer 163a, a step of forming the cap pattern 163 by removing a portion of the cap insulating layer 163 exposed by the openings of the mask, a step of forming the first intermediate pattern 162b by removing a portion of the intermediate insulating layer 162a exposed by the cap pattern 163, a step of forming the conductive pattern 161 by removing a portion of the conductive layer 161a exposed by the first intermediate pattern 162b, and a step of removing the mask.

As shown in FIG. 9, the method of forming the display apparatus according to the embodiment of the present disclosure can include a step of forming the second intermediate pattern 162c using the first intermediate pattern 162b.

The second intermediate pattern 162c can be formed by a process of removing a portion of the first intermediate pattern 162b. A portion of the first intermediate pattern 162b can be removed by a solution capable of removing an organic insulating material constituting the intermediate insulating layer 162a. For example, the step of forming the second intermediate pattern 162c can include a wet etching process.

The conductive pattern 161 can't be removed by the solution used in a process of removing a portion of the first intermediate pattern 162b. That is, in the method of forming the display apparatus according to the embodiment of the present disclosure, a size of the conductive pattern 161 can't be reduced in a process of forming the second intermediate pattern 162c. The cap pattern 163 can be etched relatively slowly by the solution used in a process of removing a portion of the first intermediate pattern 162b. Thus, in the method of forming the display apparatus according to the embodiment of the present disclosure, a size of the cap pattern 163 can be made smaller than a size of the conductive pattern 161 by a process of removing a portion of the first intermediate pattern 162b, and the second intermediate pattern 162c can be formed to have a smaller size than the cap pattern 163. The edge of the conductive pattern 161 and the edge of the cap pattern 163 can be disposed outside the second intermediate pattern 162c. For example, the side surface 162s of the second intermediate pattern 162c can overlap the upper surface of the conductive pattern 161 and the lower surface of the cap pattern 163. Therefore, in the method of forming the display apparatus according to the embodiment of the present disclosure, the under-cut region UC by the second intermediate pattern 162c and the cap pattern 163 can be formed.

A lower end portion of the first intermediate pattern 162b in contact with the conductive pattern 161 and an upper end portion of the first intermediate pattern 162b in contact with the cap pattern 163 can be etched slower than the central portion of the first intermediate pattern 162b. For example, the side surface 162s of the second intermediate pattern 162c can be formed to have a concave shape with respect to the central portion of the second intermediate pattern 162c.

The bank insulating layer 150 can't be affected by the solution used in a process of removing a portion of the first intermediate pattern 162b. For example, the step of forming the bank insulating layer 150 can include a step of partially curing the bank insulating layer 150 and a step of removing an uncured portion of the bank insulating layer 150. Thus, in the method of forming the display apparatus according to the embodiment of the present disclosure, the damage of the bank insulating layer 150 due to a process of forming the second intermediate pattern 162b can be prevented. And, in the method of forming the display apparatus according to the embodiment of the present disclosure, a size deviation of the emission area EA defined in each pixel area PA due to a process of forming the second intermediate pattern 162b can be prevented.

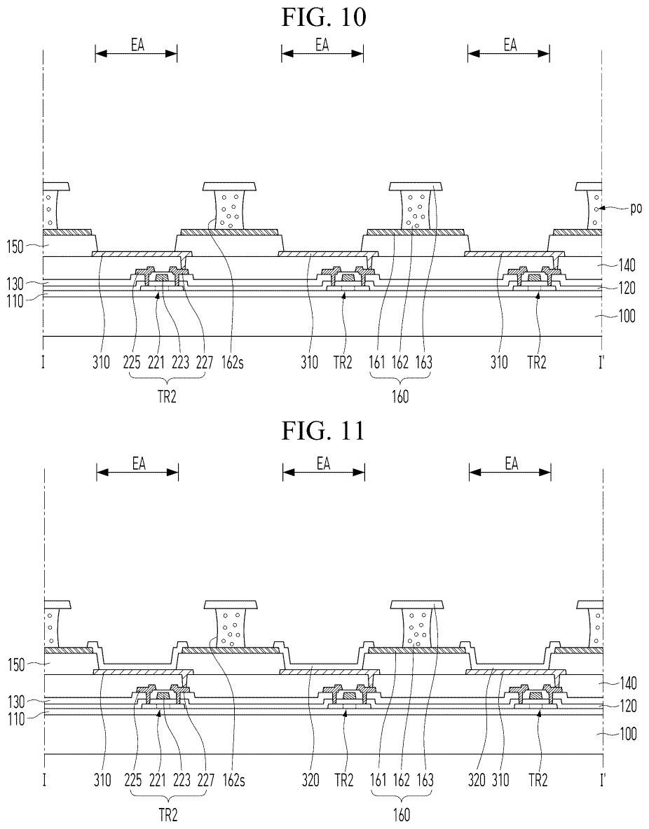

As shown in FIG. 10, the method of forming the display apparatus according to the embodiment of the present disclosure can include a step of forming the porous layer 162 using the second intermediate pattern 162c.

The step of forming the porous layer 162 can include a step of forming the plurality of fine pores po in the second intermediate pattern 162c by removing the plurality of fine particles mp. A process of removing the fine particles mp can include a wet process. That is, in the method of forming the display apparatus according to the embodiment of the present disclosure, the porous layer 162 can have a same shape as the second intermediate pattern 162c. The plurality of fine pores po can be dispersed in the second intermediate pattern 162c. For example, the side surface 162s of the porous layer 162 can have a concave shape with respect to the central portion of the porous layer 162. The conductive pattern 161, the porous layer 162 and the cap pattern 163 can constitute the spacer 160.

As shown in FIG. 11, the method of forming the display apparatus according to the embodiment of the present disclosure can include a step of forming the light-emitting unit 320 of each pixel area PA using the spacer 160.

The step of forming the light-emitting unit 320 of each pixel area PA can include a deposition process using the fine metal mask (FMM). For example, the step of forming the light-emitting unit 320 of each pixel area PA can include a step of preparing the fine metal mask including an opening overlapping with the emission area EA of one of the pixel areas PA, a step of supporting the fine metal mask on the spacer 160, and a step of depositing a material for the light-emitting unit 320 using the opening of the fine metal mask. Thus, in the method of forming the display apparatus according to the embodiment of the present disclosure, the light-emitting unit 320 of each pixel area PA can be formed to be spaced apart from the porous layer 162. For example, the upper surface of the conductive pattern 161 can include a region disposed between the light-emitting unit 320 of each pixel area PA and the side surface 162s of the porous layer 162.

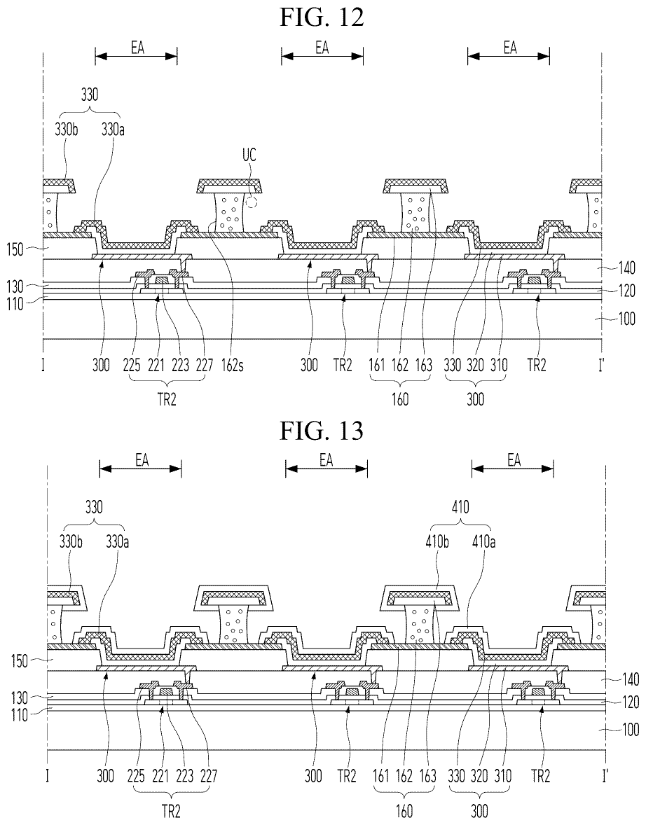

As shown in FIG. 12, the method of forming the display apparatus according to the embodiment of the present disclosure can include a step of forming the light-emitting device 300 at the emission area EA of each pixel area PA.

The step of forming the light-emitting device 300 of each pixel area PA can include a step of forming the upper electrode 330 on the entire surface of the device substrate 100 in which the light-emitting unit 320 of each pixel area PA is formed. Thus, in the method of forming the display apparatus according to the embodiment of the present disclosure, the first electrode pattern 330a disposed on the light-emitting unit 320 of each pixel area PA and the second electrode pattern 330b separated from the first electrode pattern 330a by the under-cut region UC of the spacer 160 can be simultaneously formed. That is, in the method of forming the display apparatus according to the embodiment of the present disclosure, the light-emitting device 300 of each pixel area PA can be formed simultaneously. Therefore, in the method of forming the display apparatus according to the embodiment of the present disclosure, the process efficiency can be improved.

The first electrode pattern 330a can be formed to cover the light-emitting unit 320 of each pixel area PA. For example, the first electrode pattern 330a disposed on each pixel area PA can be formed to have a larger size than the light-emitting unit 320 of the corresponding pixel area PA. The edge of the first electrode pattern 330a can be in direct contact with the upper surface of the conductive pattern 161 between the light-emitting unit 320 of each pixel area PA and the porous layer 162.

The second electrode pattern 330b can be formed on the upper surface of the cap pattern 163. The side surface 162s of the porous layer 162 can be disposed between the first electrode pattern 330a and the second electrode pattern 330b of the upper electrode 330. For example, the first electrode pattern 330a and the second electrode pattern 330b of the upper electrode 300 can't be in contact with the side surface 162s of the porous layer 162. The side surface 162s of the porous layer 162 can be exposed by the first electrode pattern 330a and the second electrode pattern 330b of the upper electrode 330.

As shown in FIG. 13, the method of forming the display apparatus according to the embodiment of the present disclosure can include a step of forming the first encapsulating layer 410 on the entire surface of the device substrate 100 in which the light-emitting devices 300 are formed.

The first encapsulating layer 410 can be formed of an inorganic insulating material. The step of forming the first encapsulating layer 410 can include a step of depositing an insulating material on the entire surface of the device substrate 100 in which the light-emitting devices 300 are formed. Thus, in the method of forming the display apparatus according to the embodiment of the present disclosure, the first encapsulating pattern 410a formed on the first electrode pattern 330a and the second encapsulating pattern 410b separated from the first encapsulating pattern 410a by the under-cut region UC of the spacer 160 can be formed simultaneously.

The first encapsulating pattern 410a can be formed to cover the first electrode pattern 330a. The second encapsulating pattern 410b can be formed to cover the second electrode pattern 330b. The second encapsulating pattern 410b can be separated from the first encapsulating pattern 410a on the side surface 162s of the porous layer 162. For example, the side surface 162s of the porous layer 162 can include a region disposed between the first encapsulating pattern 410a and the second encapsulating pattern 410b of the first encapsulating layer 410. The first encapsulating pattern 410a and the second encapsulating pattern 410b of the first encapsulating layer 410 can expose at least portion of the side surface 162s of the porous layer 162.

As shown in FIGS. 4 and 5, the method of forming the display apparatus according to the embodiment of the present disclosure can include a step of forming the second encapsulating layer 420 on the entire surface of the device substrate 100 in which the first encapsulating pattern 410a and the second encapsulating pattern 410b of the first encapsulating layer 410 are formed, and a step of forming the third encapsulating layer 430 on the second encapsulating layer 420.

The second encapsulating layer 420 can be formed of an organic insulating material. The second encapsulating layer 420 can be formed to have a thicker than the first encapsulating layer 410. For example, the spacer 160 can be covered by the second encapsulating layer 420. The second encapsulating layer 420 can be in direct contact with the side surface 162s of the porous layer 162 between the first encapsulating pattern 410a and the second encapsulating pattern 410b. Thus, in the method of forming the display apparatus according to the embodiment of the present disclosure, a portion of the second encapsulating layer 420 can penetrate the fine pores po of the porous layer 162. That is, in the method of forming the display apparatus according to the embodiment of the present disclosure, the organic insulating material coated in each pixel area PA can move onto adjacent pixel area PA through the fine pores po of the porous layer 162 in a process of forming the second encapsulating layer 420. Therefore, in the method of forming the display apparatus according to the embodiment of the present disclosure, the fluidity of the second encapsulating layer 420 can be increased. For example, in the method of forming the display apparatus according to the embodiment of the present disclosure, a level of the upper surface of the second encapsulating layer 420 formed on each pixel area PA can be the same as a level of the upper surface of the second encapsulating layer 420 formed on adjacent pixel area PA.

The third encapsulating layer 430 can be formed on an inorganic insulating material. The third encapsulating layer 430 can be in direct contact with the upper surface of the second encapsulating layer 420 covering the light-emitting device 300 of each pixel area PA and the spacer 160. Thus, in the method of forming the display apparatus according to the embodiment of the present disclosure, the third encapsulating layer 430 can't be separated by the spacer 160. For example, the method of forming the display apparatus according to the embodiment of the present disclosure, the third encapsulating layer 430 can be formed to be a flat plate shape.

Accordingly, the display apparatus according to the embodiment of the present disclosure can comprise the spacer 160 disposed on the upper surface of the bank insulating layer 150, wherein the spacer 160 can include the porous layer 162 disposed between the conductive pattern 161 and the cap pattern 163, wherein the upper electrode 330 and the first encapsulating layer 410 can be partially separated by the under-cut region UC formed by the porous layer 162 and the cap pattern 163, and wherein the second encapsulating layer 420 can be in direct contact with the side surface 162s of the porous layer 162 between the conductive pattern 161 and the cap pattern 163. Thus, in the display apparatus according to the embodiment of the present disclosure, the upper surface of the second encapsulating layer 420 formed on each pixel area PA can have the same level. That is, in the display apparatus according to the embodiment of the present disclosure, a difference in level of the upper surface of the encapsulation structure 400 on each pixel area PA can be prevented by the porous layer 162 including the plurality of fine pores po. Therefore, in the display apparatus according to the embodiment of the present disclosure, stains due to a difference in level of the upper surface of the encapsulation structure 400 can be prevented.

And, in the display apparatus according to the embodiment of the present disclosure, a difference in level of the upper surface of the encapsulation structure 400 can be prevented by the porous layer 162 of the spacer 160. That is, in the display apparatus according to the embodiment of the present disclosure, a process of forming the upper electrode 330, the first encapsulating layer 410 and the second encapsulating layer 420 so that the upper surface of the second encapsulation layer 420 on each pixel area PA has the same level can be simplified. Therefore, in the display apparatus according to the embodiment of the present disclosure, the production energy can be reduced by process optimization.

The display apparatus according to the embodiment of the present disclosure is described that the driving circuit DC of each pixel area PA consists of the first thin film transistor TR1, the second thin film transistor TR2 and the storage capacitor Cst. However, in the display apparatus according to another embodiment of the present disclosure, the driving circuit DC of each pixel area PA can include a driving thin film transistor and at least one switching thin film transistor. For example, in the display apparatus according to another embodiment of the present disclosure, the driving circuit DC of each pixel area PA can further include a third thin film transistor to initialize the storage capacitor Cst of the corresponding pixel area PA according to the gate signal. The third thin film transistor of each pixel area PA can include a third semiconductor pattern, a third gate electrode, a third drain electrode and a third source electrode. The third semiconductor pattern of each pixel area PA can include a semiconductor material. The third gate electrode of each pixel area PA can be electrically connected to the gate line GL. The third drain electrode of each pixel area PA can be electrically connected to an initial line applying an initial signal. The third source electrode of each pixel area PA can be electrically connected to the storage capacitor Cst. Thus, in the display apparatus according to another embodiment of the present disclosure, the degree of freedom in the configuration of the driving circuit DC in each pixel area PA can be improved.

In the display apparatus according to the embodiment of the present disclosure, the location and the electric connection of the first drain electrode, the first source electrode, the second drain electrodes 225 and the second source electrode 227 of each driving circuit DC can vary depending on the configuration of the corresponding driving circuit DC and/or the type of the corresponding thin film transistors TR1 and TR2. For example, in the display apparatus according to another embodiment of the present disclosure, the second gate electrode 223 of each driving circuit DC can be electrically connected to the first drain electrode of the corresponding driving circuit DC. Thus, in the display apparatus according to another embodiment of the present disclosure, the degree of freedom in the configuration of each driving circuit DC and the type of each thin film transistor TR1 and TR2 can be improved.

The display apparatus according to the embodiment of the present disclosure is described that the plurality of fine particles mp includes a metal. However, in the display apparatus according to another embodiment of the present disclosure, the plurality of fine particles mp can be formed of various materials having an etch selectivity with the porous layer 162. For example, in the display apparatus according to another embodiment of the present disclosure, the plurality of fine particles mp can be formed of an inorganic insulating material. Thus, in the display apparatus according to another embodiment of the present disclosure, the plurality of fine particles mp can be removed by the solution used in a process of selectively etching the first intermediate pattern 162a. That is, in the display apparatus according to another embodiment of the present disclosure, a step of selectively removing a portion of the first intermediate pattern 162a and a step of forming the plurality of fine pores po can be performed simultaneously. Therefore, in the display apparatus according to another embodiment of the present disclosure, a process of forming the porous layer 162 can be simplified. And, in the display apparatus according to another embodiment of the present disclosure, the process efficiency can be improved.

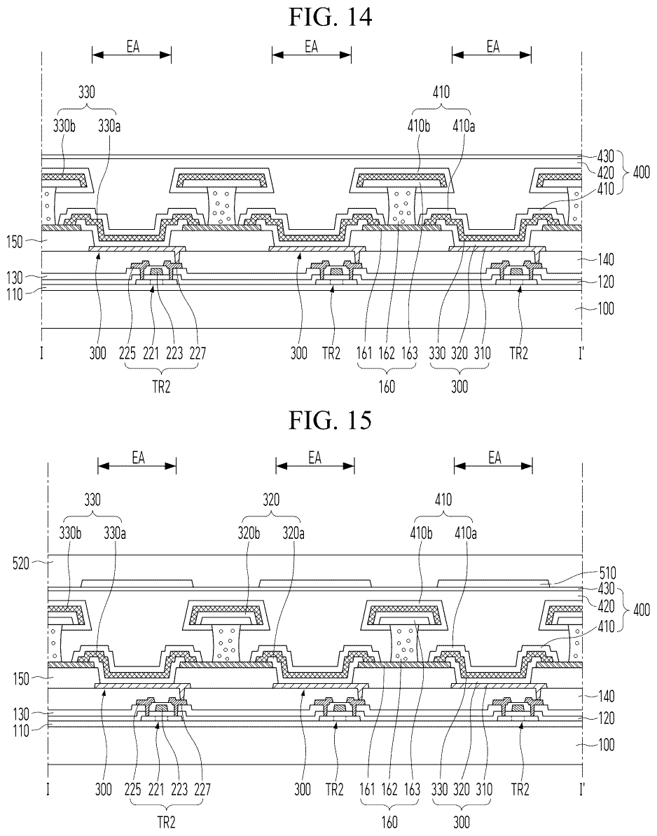

The display apparatus according to the embodiment of the present disclosure is described that the cap pattern 163 is removed relatively slowly in a process of forming the second intermediate pattern 162b. However, in the display apparatus according to another embodiment of the present disclosure, a size of the cap pattern 163 can't be reduced by the solution used in a process of forming the second intermediate pattern 162b. For example, in the display apparatus according to another embodiment of the present disclosure, the cap pattern 163 can have a same size as the conductive pattern 161, as shown in FIG. 14. The cap pattern 163 can be formed of a material having an etch selectivity with the porous layer 162. For example, the cap pattern 163 can be formed of a metal oxide. Thus, in the display apparatus according to another embodiment of the present disclosure, the under-cut region UC of the spacer 160 can be effectively formed. That is, in the display apparatus according to another embodiment of the present disclosure, a contact area between the porous layer 162 and the second encapsulating layer 420 can be effectively secured. Therefore, in the display apparatus according to another embodiment of the present disclosure, stains due to a difference in level of the upper surface of the second encapsulating layer 420 can be effectively prevented.

The display apparatus according to the embodiment of the present disclosure is described that the step of forming the light-emitting unit 320 of each pixel area PA includes a deposition process using the fine metal mask. However, in the display apparatus according to another embodiment of the present disclosure, the light-emitting unit 320 of each pixel area PA can be formed simultaneously with the light-emitting unit 320 of adjacent pixel area PA. For example, in the display apparatus according to another embodiment of the present disclosure, the light-emitting unit 320 can include an emission portion 320a overlapping with the emission area EA of each pixel area PA and a separation portion 320b separated from the emission portion 320a by the under-cut region of the spacer 160, as shown in FIG. 15. The emission portion 320a disposed between the lower electrode 310 and the first electrode pattern 330a of each pixel area PA can generate and emit light, and light can't be generated and emitted from the separation portion 320b disposed between the cap pattern 163 and the second electrode pattern 330b.

The light emitted from the light-emitting device 300 of each pixel area PA can display a same color as the light emitted from the light-emitting device 300 of adjacent pixel area PA. For example, the light-emitting device 300 of each pixel area PA can emit white light. In the display apparatus according to another embodiment of the present disclosure, color filters 510 can be disposed on the encapsulation structure 400, and a filter passivation layer 520 can be disposed on the color filters 510.

Each of the color filters 510 can overlap the emission area EA of one of the pixel areas PA. For example, the light generated from the light-emitting device 300 of each pixel area PA can be emitted through the color filer 510 disposed on the corresponding pixel area PA. The color filter 510 of each pixel area PA can include a different material from the color filer 510 of adjacent pixel area PA. For example, the color filter 510 of each pixel area PA can be one of a red color filter, a green color filter and a blue color filter. Thus, in the display apparatus according to another embodiment of the present disclosure, the image having various colors can be realized by the color filter 510 of each pixel area PA. That is, in the display apparatus according to another embodiment of the present disclosure, stains due to a difference in level of the upper surface of the second encapsulating layer 420 formed on each pixel area PA can be prevented, regardless of a method of forming the light-emitting unit 320. Therefore, in the display apparatus according to another embodiment of the present disclosure, the degree of freedom in a process of forming the light-emitting unit 320.

The filter passivation layer 520 can prevent the damage of the color filters 510 due to the external impact. For example, each of the color filters 510 can be completely covered by the filter passivation layer 520. The filter passivation layer 520 can include an insulating material. For example, the filter passivation layer 520 can include an inorganic insulating material and/or an organic insulating material. An upper surface of the filter passivation layer 520 opposite to the device substrate 100 can be flat. Thus, in the display apparatus according to another embodiment of the present disclosure, the occurrence of stains due to curvature of the upper surface of the filter passivation layer 520 can be prevented. And, in the display apparatus according to another embodiment of the present disclosure, the damage of the color filters 510 due to the external impact can be effectively prevented.

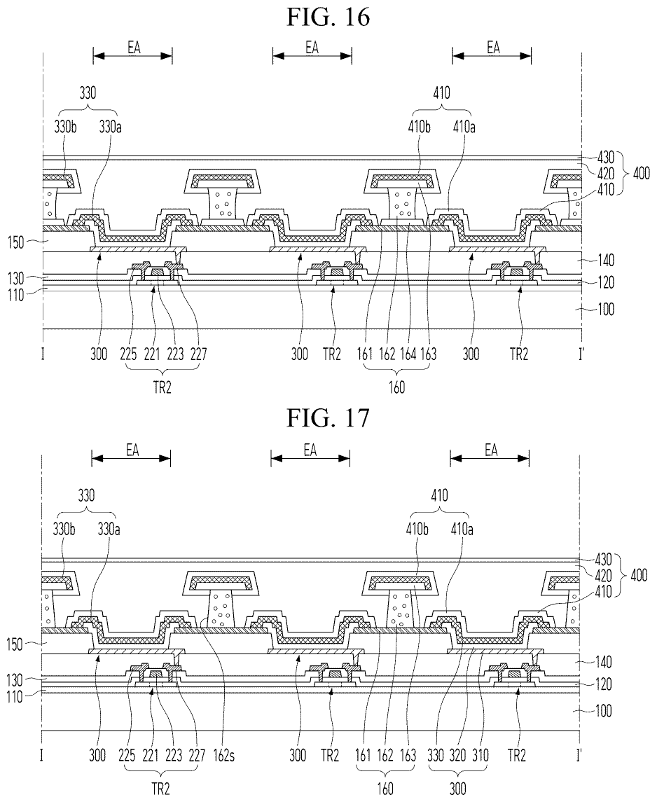

The display apparatus according to the embodiment of the present disclosure is described that the porous layer 162 is in direct contact with the upper surface of the conductive pattern 161 and the lower surface of the cap pattern 163. However, in the display apparatus according to another embodiment of the present invention, the porous layer 162 can be spaced apart from the conductive pattern 161 and/or the cap pattern 163. For example, in the display apparatus according to another embodiment of the present disclosure, the spacer 160 can include a buffer pattern 164 disposed between the conductive pattern 161 and the porous layer 162, as shown in FIG. 16.

The buffer pattern 164 can include a different material from the porous layer 162. The buffer pattern 164 can include a material relatively slowly removed by the solution used in a process of etching the porous layer 162. For example, the buffer pattern 164 can include an inorganic insulating material. An edge of the buffer pattern 164 can be disposed outside the porous layer 162. The buffer pattern 164 can have a smaller size than the conductive pattern 161.

An area of the porous layer 162 exposed by the first encapsulating pattern 410a and the second encapsulating pattern 410b of the first encapsulating layer 410 can be increased by the buffer pattern 164. For example, the buffer pattern 164 can have a same thickness as the first encapsulating layer 410. Thus, in the display apparatus according to another embodiment of the present disclosure, a contact area between the second encapsulating layer 420 and the porous layer 162 can be sufficiently secured. Therefore, in the display apparatus according to another embodiment of the present disclosure, the fluidity of the second encapsulating layer 420 can be effectively improved. That is, in the display apparatus according to another embodiment of the present disclosure, stains due to a difference in level of the upper surface of the second encapsulating layer 420 can be effectively prevented.

The display apparatus according to the embodiment of the present disclosure is described that the side surface 162s of the porous layer 162 has a concave shape with respect to the central portion of the porous layer 162. However, in the display apparatus according to another embodiment of the present invention, the side surface 162s of the porous layer 162 can have various shapes. For example, in the display apparatus according to another embodiment of the present disclose, the side surface of the porous layer 162 can be formed to have a positive taper, as shown in FIG. 17. Thus, in the display apparatus according to another embodiment of the present disclosure, the under-cut region by the porous layer 162 and the cap pattern 163 can be effectively formed.

In the display apparatus according to another embodiment of the present disclosure, the step of forming the porous layer 162 can include an exposure process. For example, in the display apparatus according to another embodiment of the present disclosure, the step of forming the porous layer 162 can include a step of forming an inorganic insulating layer made of an organic insulating material in which the plurality of fine particles is dispersed on the conductive pattern 161, a step of exposing a portion of the organic insulating layer overlapping with the emission area EA of each pixel area PA, a step of forming the cap pattern 163 on the organic insulating layer, a step of forming an organic pattern by removing an exposed portion of the organic insulating layer by a space between adjacent cap patterns 163, and a step of forming the porous layer 162 by removing the plurality of fine particles dispersed in the organic pattern. Thus, in the display apparatus according to another embodiment of the present disclosure, the degree of freedom in a process of forming the porous layer 162 and a shape of the side surface of the porous layer 162 can be improved.

The display apparatus according to the embodiment of the present disclosure is described that the reduction in the size of the bank insulating layer 150 due to a process of forming the porous layer 162 is prevented by a curing process. However, in the display apparatus according to another embodiment of the present invention, the porous layer 162 can have same characteristics as the bank insulating layer 150. For example, in the display apparatus according to another embodiment of the present disclosure, the porous layer 162 can be formed of a same material as the bank insulating layer 150.

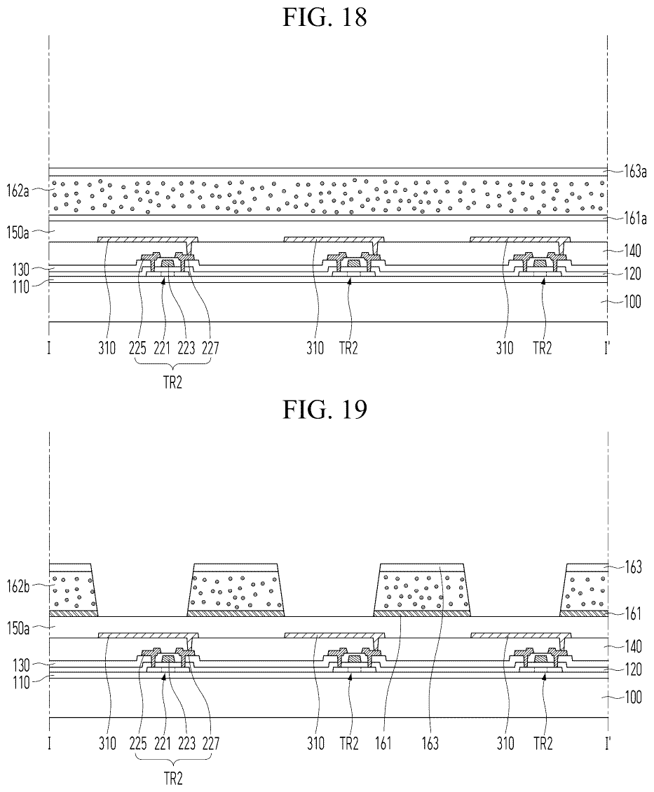

FIGS. 18 and 19 are views sequentially showing a method of forming the display apparatus according to another embodiment of the present disclosure.

The method of forming the display apparatus according to another embodiment of the present disclosure will be described with reference to FIGS. 18 and 19. First, as shown in FIG. 18, the method of forming the display apparatus according to another embodiment of the present disclosure can include a step of forming a preliminary bank layer 150a covering the lower electrode 310 of each pixel area PA, a step of forming a conductive layer 161a on the preliminary bank layer 150a, a step of forming an interlayer insulating layer 162a on the conductive layer 161a, and a step of a cap insulating layer 163a on the intermediate insulating layer 162a.

As shown in FIG. 19, the method of forming the display apparatus according to another embodiment of the present disclosure can include a step of forming the cap pattern 163 by removing a portion of the cap insulating layer 163a, a step of forming a first intermediate pattern 162b by removing a portion of the intermediate insulating layer 162a, a step of forming the conductive pattern 161 by removing a portion of the conductive layer 161a.

The conductive pattern 161, the first intermediate pattern 162b and the cap pattern 163 can be sequentially stacked on the preliminary bank layer 150a. For example, a portion of the preliminary bank layer 150a can be exposed by the conductive pattern 161. A portion of the preliminary bank layer 150a exposed by the conductive pattern 161 can be removed by a process of forming a second intermediate pattern using the first intermediate pattern 162b. That is, in the display apparatus according to another embodiment of the present disclosure, the bank insulating layer 150 defining the emission area EA in each pixel area PA can be formed simultaneously with the second intermediate pattern. Therefore, in the display apparatus according to another embodiment of the present disclosure, the process efficiency can be improved.

In the result, the display apparatus according to the embodiments of the present disclosure can comprise the bank insulating layer defining the emission area in each pixel area, the light-emitting device disposed at the emission area of each pixel area, the spacer disposed on the bank insulating layer, and the encapsulation structure covering the bank insulating layer, the light-emitting device and the spacer, wherein the encapsulation structure can include the first inorganic encapsulating layer, the organic encapsulating layer and the second inorganic encapsulating layer, wherein the spacer can include the conductive pattern, the porous layer and the cap pattern, and wherein the side surface of the porous layer can be in direct contact with the organic encapsulating layer by the under-cut formed by the porous layer and the cap pattern. Thus, in the display apparatus according to the embodiments of the present disclosure, the upper surface of the organic encapsulating layer disposed at the emission area of each pixel area can have a same level. Thereby, in the display apparatus according to the embodiments of the present disclosure, stains due to a difference in level of the upper surface of the encapsulation structure can be prevented. And, in the display apparatus according to the embodiments of the present disclosure, the production energy can be reduced by process optimization.

The description herein has been presented to enable any person skilled in the art to make, use and practice the technical features of the present disclosure, and has been provided in the context of one or more particular example applications and their example requirements. Various modifications, additions and substitutions to the described embodiments will be readily apparent to those skilled in the art, and the principles described herein may be applied to other embodiments and applications without departing from the scope of the present disclosure. The description herein and the accompanying drawings provide examples of the technical features of the present disclosure for illustrative purposes. In other words, the disclosed embodiments are intended to illustrate the scope of the technical features of the present disclosure. Thus, the scope of the present disclosure is not limited to the embodiments shown, but is to be accorded the widest scope consistent with the claims. The scope of protection of the present disclosure should be construed based on the following claims, and all technical features within the scope of equivalents thereof should be construed as being included within the scope of the present disclosure.

What is claimed is:

1. A display apparatus, comprising:
a bank insulating layer on a device substrate, the bank insulating layer defining an emission area;
a light-emitting device at the emission area of the device substrate, the light-emitting device including a lower electrode, a light-emitting unit and an upper electrode, which are sequentially stacked;
a spacer on the bank insulating layer, the spacer having a stacked structure of a conductive pattern, a porous layer and a cap pattern; and
an encapsulation structure on the bank insulating layer, the light-emitting device and the spacer,
wherein the encapsulation structure includes a first inorganic encapsulating layer, an organic encapsulating layer and a second inorganic encapsulating layer, which are sequentially stacked,
wherein the spacer has an under-cut region by the porous layer and the cap pattern, and
wherein a side surface of the porous layer includes a region exposed by the upper electrode and the first inorganic encapsulating layer.

2. The display apparatus according to claim 1, wherein the organic encapsulating layer is in contact with the side surface of the porous layer exposed by the upper electrode and the first inorganic encapsulating layer.

3. The display apparatus according to claim 1, wherein the conductive pattern and the cap pattern include a material having an etch selectivity with the porous layer.

4. The display apparatus according to claim 3, wherein the side surface of the porous layer has a concave shape with respect to a central portion of the porous layer.

5. The display apparatus according to claim 1, wherein the conductive pattern includes a conductive material,
wherein the upper electrode includes a first electrode pattern overlapping with the emission area and a second electrode pattern separated from the first electrode pattern by the under-cut region, and
wherein the first electrode pattern is in contact with the conductive pattern between the light-emitting unit and the porous layer.

6. The display apparatus according to claim 5, wherein the second electrode pattern includes a same material as the first electrode pattern, and
wherein resistance of the conductive pattern is lower than resistance of the first electrode pattern and resistance of the second electrode pattern.

7. The display apparatus according to claim 1, wherein the first inorganic encapsulating layer includes a first encapsulating pattern overlapping with a first electrode pattern and a second encapsulating pattern overlapping with a second electrode pattern, and
wherein the second encapsulating pattern is separated from the first encapsulating pattern by the under-cut region.

8. The display apparatus according to claim 1, wherein a thickness of the porous layer is greater than a thickness of the first inorganic encapsulating layer.

9. The display apparatus according to claim 1, wherein the spacer further includes a buffer pattern disposed between the conductive pattern and the porous layer, and
wherein the buffer pattern includes a material having an etch selectivity with the porous layer.

10. The display apparatus according to claim 9, wherein the buffer pattern includes an inorganic insulating material.

11. The display apparatus according to claim 9, wherein a thickness of the buffer pattern is same as a thickness of the first inorganic encapsulating layer.

12. The display apparatus according to claim 1, wherein the porous layer includes a same material as the bank insulating layer.
